(19) United States
(12) Patent Application Publication
(10) Pub. No.: US 2021/0021079 A1
(43) Pub. Date: Jan. 21, 2021

(54) CONVERGED POWER AND NETWORK MANAGEMENT SYSTEM

(71) Applicant: Senao Networks, Inc., Taoyuan City (TW)

(72) Inventors: Pi-Kuang Ku, Taoyuan (TW); Ming-Tao Chang, Taoyuan (TW); Wen-Tang Lee, Taoyuan (TW)

(21) Appl. No.: 16/699,696

(22) Filed: Dec. 1, 2019

(30) Foreign Application Priority Data
Jul. 17, 2019 (TW) 108209302

(51) Int. Cl. H01R 13/514; H02B 1/26; H01R 25/00

(52) U.S. Cl. CPC H01R 13/514; H01R 25/006; H02B 1/26

(57) ABSTRACT

A converged power and network management system comprises a modular power distribution unit and a modular network switch unit. The modular power distribution unit and modular network switch unit may be physically and electrically engaged, which enables the modular power distribution unit to provide power to the modular network switch.

### BACKGROUND

This application claims the benefit of Taiwan Patent Application No. 108209302, filed on Jul. 17, 2019.

This disclosure relates to a converged power and network management system particularly suitable for use with large server deployments, such as in data centers and for cloud server rack infrastructures.

The development of new network-enabled services such as e-commerce, social networking, streaming media, and the Internet of Things has placed ever greater demands on data centers and server infrastructures. Ever more amounts of storage and compute are needed to support today's services and to enable future innovations. It is important for data centers to operate more efficiently and to increase the amount of storage and compute resources that can be made available to businesses that rely on them.

Servers are commonly installed in racks in conjunction with auxiliary equipment such as power distribution units (PDUs) and network switches. PDUs are used to manage and distribute electrical power to servers, network equipment, and other devices housed in a data center. PDUs may be equipped with a variety of power sockets and other input/output jacks to meet the different needs of customers, such as to support plugs for servers having different power requirements and/or imported from other countries. Network switches are used to route and manage traffic in a network. Switches may include features such as segregating a network into branches and VLANs (virtual local area networks), split the network data flow, or quarantine data faults in a branch. High quality switches help to make networks more efficient, which in turn improves the operating efficiency of servers on the network.

There is a need for a new type of device that provides the essential functionality of PDUs and switches in a compact form factor that is easily expandable.

### BRIEF DESCRIPTION OF THE DRAWINGS

Various embodiments in accordance with the present disclosure will be described with reference to the drawings, in which:

FIG. 1 illustrates a three-way view showing the modular power distribution unit of an embodiment of a converged power and network management system.

FIG. 2 illustrates a three-way view showing the modular network switch unit of an embodiment of a converged power and network management system.

FIG. 3-1 to FIG. 3-3 illustrate the integration of the modular power distribution and network switch units of an embodiment of a converged power and network management system.

### DETAILED DESCRIPTION

Systems and methods in accordance with various embodiments of the present disclosure may overcome one or more of the aforementioned and other deficiencies experienced in conventional power management and networking devices.

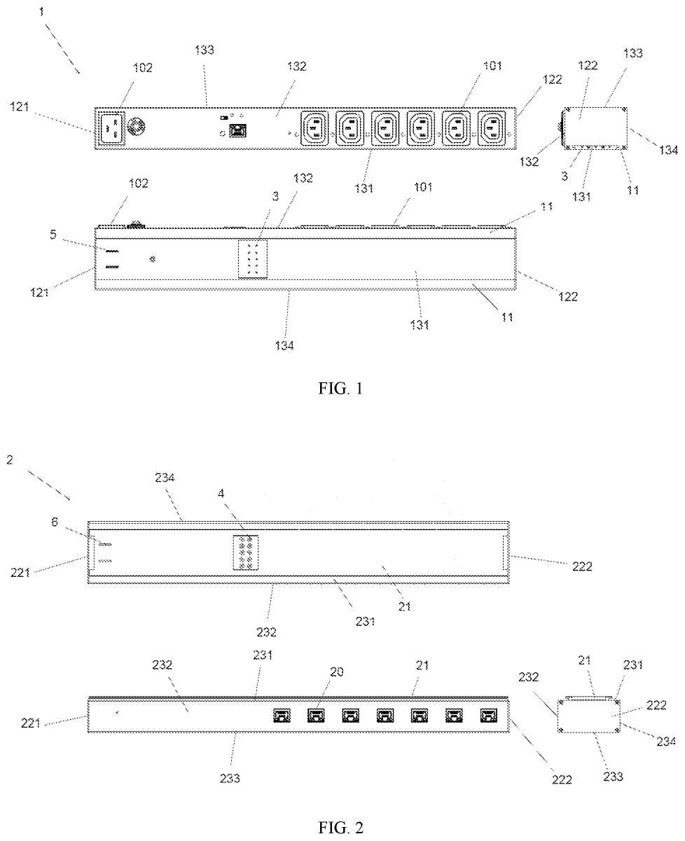

FIG. 1 illustrates a three-way view showing the modular power distribution unit (PDU) of an embodiment of a converged power and network management system.

In one embodiment, modular PDU 1 comprises six surfaces which, for ease of reference, are referred to as first end surface 121, second end surface 122, bottom surface 131, front surface 132, top surface 133, and back surface 134. Modular PDU 1 comprises a plurality of power outlets 101 which may be used to provide power to other devices. Power socket 102 provides a connection for a power cable to deliver power to the modular PDU 1 which it then distributes to other devices through power outlets 101.

Modular PDU 1 comprises various physical features that may be used to interface the modular PDU with modular network switch unit 2 to be described in more detail below. These may include connector 3, which may comprise a series of spring-loaded pins (pogo pins), tabs 5, which may also be spring-loaded, and rail slots 11.

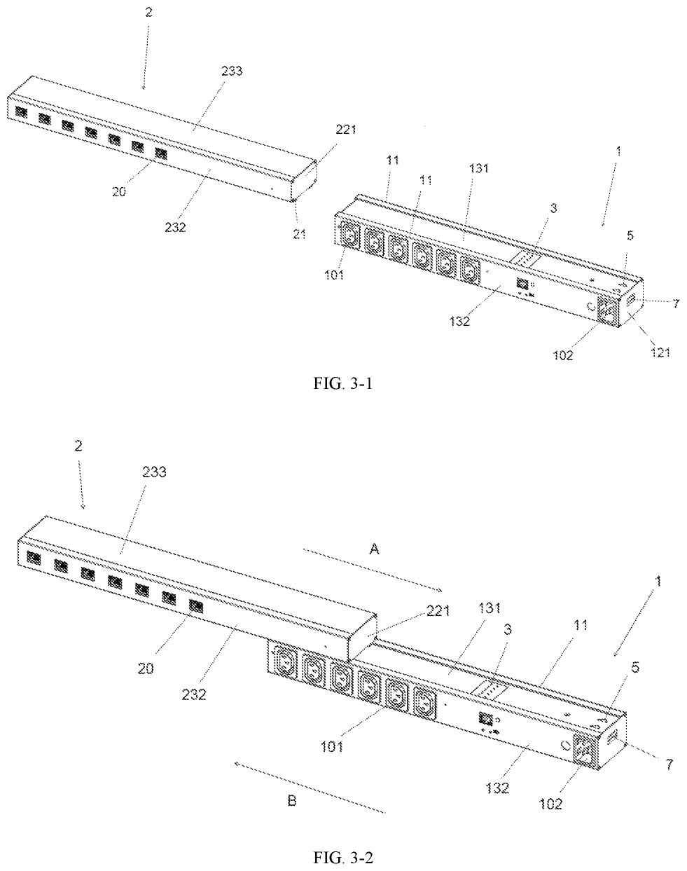

FIG. 2 illustrates a three-way view showing the modular network switch unit of an embodiment of a converged power and network management system.

In one embodiment, modular network switch 2 comprises six surfaces which, for ease of reference, are referred to as first end surface 221, second end surface 222, bottom surface 231, front surface 232, top surface 233, and back surface 234. Modular network switch 2 comprises a plurality of network interfaces 20, which may be Ethernet ports providing networking functionality and/or optionally Power over Ethernet (PoE) functionality to other devices such as servers and storage units.

Modular network switch 2 comprises various physical features that may be used to interface the modular network switch with the modular PDU 1 described above. Connector 4 comprises a series of holes into which the spring-loaded pins of connector 3 of the modular PDU 1 may be inserted. The spring-loaded tabs 5 of the modular PDU 1 may be inserted into the tab slots 6 of the modular network switch. Guide rails 21 may be inserted into the rail slots 11 on the modular PDU 1. The use of these interface technologies ensures that a secure connection can be made between the modular PDU and modular network switch.

FIG. 3-1 to FIG. 3-3 illustrate the integration of the modular power distribution and network switch units of an embodiment of a converged power and network management system.

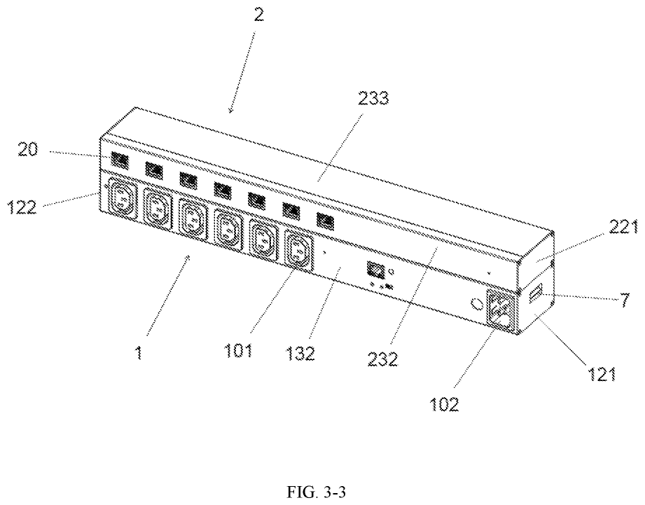

FIG. 3-1 illustrates the modular PDU 1 and modular network switch 2 as separate units before they are integrated. FIG. 3-2 shows that the modular PDU 1 and modular network switch 2 are physically engaging with each other as the guide rails 21 on the modular network switch 2 are inserted into the rail guides 11 on the modular PDU 1. Modular network switch 2 can be moved, while engaged with modular PDU 1, in direction A relative to the position of the modular PDU. Similarly, modular PDU 1 moves in direction B relative to the position of modular network switch 2.

FIG. 3-3 illustrates the modular PDU 1 and network switch 2 as fully engaged and integrated. In this state, the two units are able to act as a single unit. The spring-loaded tabs 5 are engaged with the tab slots 6, locking the two units together, and causing the physical switch 7 to be engaged. To separate the two units, a user can disengage switch 7 to release the spring-loaded tabs 5 from the tab slots 6.

When the modular PDU 1 and network switch 2 are fully engaged and integrated, the spring-loaded pins of connector 3 are inserted into the holes of connector 4. The pins are electrically conductive, and this connection thus creates a pathway for power to be delivered from modular PDU 1 to modular network switch 2, and optionally via PoE to Ethernet devices connected to the modular network switch 2.

It would be appreciated that the modular PDU and modular network switch could be made to have different features in accordance with differing requirements. For instance, the modular PDU may be include more sockets and/or may be made to be able to deliver more or less total power output. The modular network switch may be made with different physical network interfaces instead of or in addition to Ethernet. It may also incorporate Power over Ethernet functionality or any variety of networking features at different layers of the standard network model.

The system described here reduces the cost and complexity of deploying a complex network such as a network of high-availability servers in a data center providing the backend for cloud services.

As used in the above description and in the claims that follow, words such as “a,” “an,” and “the” include plural references unless the context clearly indicates otherwise. Also, as used in the description herein and throughout the claims that follow, the meaning of “in” includes “in” and “on” unless the context clearly indicates otherwise.

The above description illustrations various embodiments along with examples of how aspects of some embodiments may be implemented. These illustrations are not necessarily intended to limit the scope of the inventions described herein and as defined by the following claims. Based on the above disclosure and the following claims, other arrangements, embodiments, implementations and equivalents may be employed without departing from the scope hereof as defined by the claims.

What is claimed is:

1. An apparatus comprising:
a modular power distribution unit having a plurality of power sockets and at least a first surface having a first connection unit,
a modular network switch unit having a plurality of network ports and at least a second surface having a second connection unit,
wherein the modular power distribution unit may be connected to the modular network switch through the first connection unit and second connection unit, and
wherein the modular power distribution unit may provide power to the modular network switch when the modular power distribution unit is connected to the modular network switch.

2. The apparatus of claim 1, wherein:
the first surface of the modular power distribution further comprises electrically conductive pins,
the second surface of the modular network switch further comprises electrically conductive pin holes corresponding to the pins,
wherein the modular distribution unit may transmit power to the modular network switch through the pins.

3. The apparatus of claim 2, wherein:
the modular network switch may transmit power to devices connected to one or more of the network ports.
